(19) United States
(12) Patent Application Publication
(10) Pub. No.: US 2007/0293014 A1
(43) Pub. Date: Dec. 20, 2007

(54) METHOD FOR FORMING METAL-INSULATOR-METAL CAPACITOR OF SEMICONDUCTOR DEVICE

(75) Inventor: Yung Pil KIM, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: DONGBU HITEK CO., LTD., Seoul (KR)

(21) Appl. No.: 11/762,188

(22) Filed: Jun. 13, 2007

(30) Foreign Application Priority Data
Jun. 15, 2006 (KR) 10-2006-0053869

(51) Int. Cl. H01L 21/20

(52) U.S. Cl. 438/381

(57) ABSTRACT

A method for forming a Metal-Insulator-Metal capacitor of a semiconductor device includes forming an insulation layer, a lower conductive layer, a dielectric layer and an upper conductive layer on a semiconductor substrate; forming, on the upper conductive layer, a protective insulation layer wherein an etching selectivity of the lower conductive layer to the protective insulation layer is high, patterning the upper conductive layer to form an upper electrode, patterning the lower conductive layer to form a lower electrode, depositing and planarizing an insulation layer, forming a via contact, and forming a metal wiring layer. Therefore, a process margin in the follow-up etching process is increased although the photosensitive film is reduced in its thickness.

### FIELD OF THE INVENTION

The present invention relates to a method for forming a metal-insulator-metal (MIM) capacitor of a semiconductor device and, more particularly, to a method for forming a MIM capacitor of a semiconductor device in which a capacitor is formed with upper and lower metal layers in a multilayer wiring process for fabricating the semiconductor device.

### BACKGROUND OF THE INVENTION

In general, an analog capacitor, employed in a CMOS logic device that requires stable characteristics, is formed with various structures such as a polysilicon-insulator-polysilicon (PIP), polysilicon-insulator-metal (PIM), metal-insulator-polysilicon (MIP), and the MIM, etc. Such analog capacitor is applied as a core technology in the field of an A/D converter and a switching capacitor filter.

FIGS. 1A to 1D are sectional views showing a conventional process of forming a MIM capacitor. First, as shown in FIG. 1A, on a semiconductor substrate 10 on which a certain lower structure of basic semiconductor elements (not shown) and wiring (not shown) has been formed and an insulation layer 20 has been deposited, there are sequentially deposited a lower conductive layer 30, a dielectric film 40 and an upper conductive layer 50.

The lower conductive layer 30 is formed of the same layer as a general metallic wiring layer. For example, the lower conductive layer can be a composite layer formed by stacking a first Ti/TiN layer 31, an Al—Cu layer 32 and a second Ti/TiN layer 33. The dielectric film 40 should be less susceptible to a voltage drop and a leakage current and is formed of a silicon nitride (SiN) film or a silicon oxide nitride (SiON) film having a thickness of about 0.1 μm or less. In order for a following photolithography process on a metallic layer to be performed easily and accurately, the upper conductive layer 50 is preferably formed of a Ti/TiN composite film and preferably has a thickness of 0.2 μm or less.

As shown in FIG. 1B, after a photosensitive film 60 is coated on the resulting structure of FIG. 1A, a photolithography process is performed thereon to pattern the upper conductive layer 50 and the dielectric film 40. After the remaining photosensitive film is stripped, the photosensitive film 60 is coated again, and the photolithography and etching processes are performed to pattern the lower conductive layer to form a metal wiring of a general logic circuit and the lower electrode of a MIM capacitor, as shown in FIG. 1C.

Thereafter, an insulation layer 70 is deposited on the resulting structure of FIG. 1C, and is then planarized. And then, processes of forming via contact 80 and metallic wiring 90 are performed as shown in FIG. 1D. As the processes of forming the via contact 80 and metallic wiring 90 are similar to the known semiconductor process, a description thereof will be omitted.

As the design rule of the semiconductor device becomes increasingly finer, the thickness of the photosensitive film in the photolithography process is reduced, thereby causing a problem in that a process margin in a follow-up etching process is reduced. For example, in a 0.13 μm process technique as shown in FIG. 2, a design rule for forming a wiring part (a) of a general logic device by using the lower metal is 0.2 μm. And in order to form such a fine pattern, not only a Deep UV exposure equipment with high resolution is required, but the photosensitive film also should have a thickness of 0.6 μm or less. If the thickness of the photosensitive film is 0.6 μm, the thickness (c) of the photosensitive film above an upper electrode of the MIM capacitor is to be about 0.3 μm or less. Therefore, in a follow-up etching process for forming lower electrode, the photosensitive film may be consumed to cause a problem that even the upper electrode is etched (see, a portion ‘A’ in FIG. 1C). Such damage of the upper electrode may cause a severe defect in fabricating an analog capacitor that requires stable characteristics.

### SUMMARY OF THE INVENTION

It is an object of the invention to provide a method for forming a MIM capacitor of a semiconductor device capable of enhancing a process margin in an etching process although a thin photosensitive film is used according to a design rule which becomes increasingly finer.

According to an aspect of the present invention, there is provided a method for forming a MIM (Metal-Insulator-Metal) capacitor of a semiconductor device, comprising:

forming an insulation layer, a lower conductive layer, a dielectric layer and an upper conductive layer on a semiconductor substrate;

forming, on the upper conductive layer, an protective insulation layer wherein an etching selectivity of the lower conductive layer to the protective insulation layer is high;

patterning the upper conductive layer to form an upper electrode;

patterning the lower conductive layer to form a lower electrode;

depositing and planarizing an insulation layer;

forming a via contact; and

forming a metal wiring layer.

According to another aspect of the present invention, a photosensitive film used in the photolithography process for patterning the lower conductive layer has a thickness of 0.55 μm˜0.75 μm.

Further, an etching selectivity of the lower conductive layer with respect to the insulating protection layer is between 5 and 10.

### BRIEF DESCRIPTION OF THE DRAWINGS

The above and other objects and features of the present invention will become apparent from the following description of embodiments given in conjunction with the accompanying drawings, in which:

FIGS. 1A to 1D are sectional views sequentially showing the processes of forming a MIM capacitor according to a prior art;

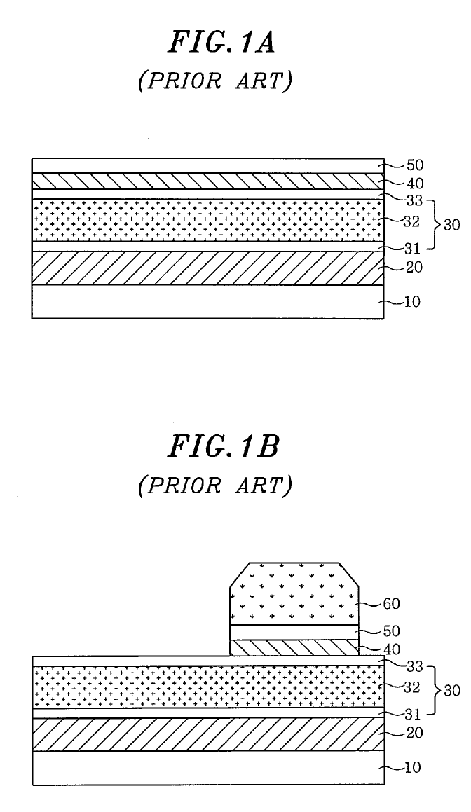

FIG. 2 is a sectional view for explaining a design rule of a 0.13 μm process technique and a photosensitive film according to a prior art; and

FIG. 3 is a sectional view showing the structure of a MIM (Metal-Insulator-Metal) fabricated in accordance with a method for forming a MIM capacitor of a semiconductor device of the present invention.

### DETAILED DESCRIPTION OF THE PREFERRED EMBODIMENTS

Hereinafter, embodiments in accordance with the present invention will be described in detail with the accompanying drawings.

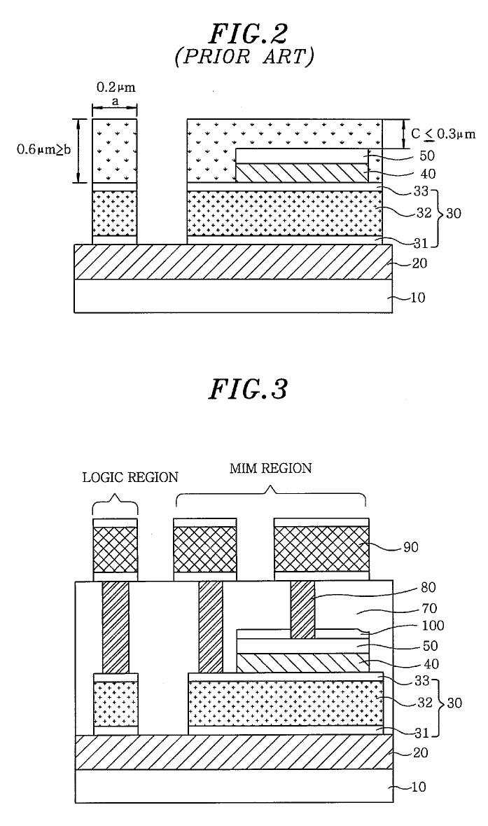

Referring to FIG. 3, there is illustrated a sectional view showing the structure of a MIM capacitor fabricated in accordance with a method for forming a MIM capacitor of a semiconductor device of the present invention.

The method for forming a MIM capacitor of a semiconductor device according to an exemplary embodiment of the present invention includes first to fourth steps.

In the first step, on a semiconductor substrate 10 where basic semiconductor elements and wirings have been formed and an insulation layer 20 has also been deposited, a lower conductive layer 30, a dielectric film 40, an upper conductive layer 50, and an protective insulation layer 100 are sequentially formed. The structure of the lower conductive layer 30, the dielectric film 40 and the upper conductive layer 50 is the same as that of a conventional art, so a detailed description therefor will be omitted.

As shown in FIG. 3, the protective insulation layer 100 serves to prevent the lower conductive layer 30 from being etched due to a loss of the photosensitive film 30 during an etching process. For that purpose, an insulation film that can increase selectivity of the lower conductive layer 30 in the etching process is deposited on the upper surface of the upper conductive layer 50.

In the second step, a photolithography process is performed to pattern the upper conductive layer 30 to form the upper electrode of the MIM capacitor. Unlike the conventional art, the etching process is divided into two steps: a first step is to etch the insulation protection film, and a second step is to etch the lower conductive layer.

In the third step, the photolithography process is performed to pattern the lower conductive layer to thereby form the lower electrode of the MIM capacitor. As mentioned above, in the conventional process, the process margin in this step is small because the lower conductive layer 30 and a wiring of a general logic device are simultaneously patterned. However, according to the present invention, the protective insulation layer 100 protects the upper conductive layer 50 and thus the process margin is increased.

In the fourth step, an insulation layer is deposited and planarized, and processes of forming a via contact and metal wiring are then performed. In the etching process for the via contact to the upper electrode, the insulation layer and the insulation protection film are sequentially etched.

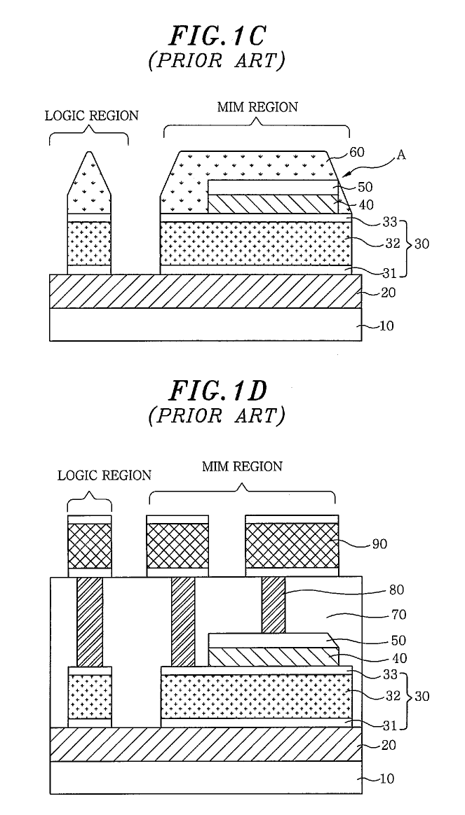

Accordingly, in the present invention, although a portion of the relatively thin photosensitive film is damaged during the etching process, the protective insulation film with high selectivity can serve to prevent the upper conductive layer from being etched. Accordingly, a MIM can be favorably formed without damaging the upper electrode as occurred in the conventional art as shown in FIG. 2C.

Alternatively, in accordance with another embodiment of the present invention, in the first step in a method for forming a MIM capacitor of a semiconductor device, preferably, the lower conductive layer is made from a composite film formed with a stacking structure of Ti/Tin/Al—Cu/Ti/TiN. Further, the upper conductive film is made from a composite film formed with a stacking structure of Ti/TiN, to thereby improve adhesion with the insulation film and serve as a reflection preventing film in a follow-up photolithography process.

In accordance with still another embodiment of the present invention, in the first step in a method for forming a MIM capacitor of a semiconductor device, preferably, the dielectric film can be formed of one of SiN, SiON, and SiO₂, and a composite film formed of a stacked structure of SiN/SiO₂, and has a thickness of 0.1 μm˜0.05 μm. Thus, a dielectric material and the thickness can be controlled according to a dielectric constant of a required capacitor.

In accordance with still another embodiment of the present invention, in the first step in a method for forming a MIM capacitor of a semiconductor device, preferably, the protective insulation film can be made of any one of SiN, SiON, and SiO₂, or a composite film formed of a stacked structure of SiN/SiO₂, and has a thickness of 0.1 μm˜0.05 μm, in order to secure a sufficient process margin in the photolithography process for forming the lower electrode.

In accordance with still another embodiment of the present invention, preferably, a photosensitive film used in the photolithography process of the third step in a method for forming a MIM capacitor of a semiconductor device has a thickness of 0.55 μm˜0.75 μm and an etching selectivity of the lower conductive layer with respect to the insulation protection film of the etching process is between 5 and 10.

Accordingly, in the photolithography process for forming the lower electrode, a sufficient depth of focus can be secured to form a fine pattern, and in the etching process, the high selectivity of the lower conductive layer to the protective insulation film can be maintained to serve as a layer for preventing the upper conductive layer from being etched to thus secure the sufficient process margin.

As described above, the method for forming the MIM capacitor of the semiconductor device according to the present invention has such an advantage that because the protective insulation layer which provides the lower conductive layer with a good selectivity is formed on the upper conductive layer, the process margin in the follow-up etching process can be increased even though the photosensitive film is reduced according to the tendency that the design rule is increasingly becoming finer. Thus, the process can be stabilized and the production yield can be improved.

Although the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method for forming a MIM (Metal-Insulator-Metal) capacitor of a semiconductor device, comprising:
forming an insulation layer, a lower conductive layer, a dielectric layer and an upper conductive layer on a semiconductor substrate;
forming, on the upper conductive layer, a protective insulation layer wherein an etching selectivity of the lower conductive layer to the protective insulation layer is high;
patterning the upper conductive layer to form an upper electrode;
patterning the lower conductive layer to form a lower electrode;
depositing and planarizing an insulation layer;
forming a via contact; and
forming a metal wiring layer.

2. The method of claim 1, wherein the lower conductive layer is a composite metal layer of Ti/TiN/Al—Cu/Ti/TiN.

3. The method of claim 1, wherein the upper conductive layer is a composite metal layer of Ti/TiN.

4. The method of claim 1, wherein the dielectric layer is made of SiN, SiON or SiO₂.

5. The method of claim 1, wherein the dielectric layer is made of a composite layer of SiN/SiO₂.

6. The method of claim 4, wherein the dielectric layer has a thickness of 0.05 μm˜0.1 μm.

7. The method of claim 5, wherein the dielectric layer has a thickness of 0.05 μm˜0.1 μm.

8. The method of claim 1, wherein the protective insulation layer is made of SiN, SiON or SiO₂.

9. The method of claim 1, wherein the protective insulation layer is a composite layer of SiN/SiO₂.

10. The method of claim 8, wherein the protective insulation layer has a thickness of 0.05 μm˜0.1 μm.

11. The method of claim 9, wherein the protective insulation layer has a thickness of 0.05 μm˜0.1 μm.

12. The method of claim 1, wherein a photosensitive film used in patterning the lower conductive layer has a thickness of 0.55 μm˜0.75 μm.

13. The method of claim 1, wherein an etching selectivity of the lower conductive layer with respect to the protective insulation layer is between 5 and 10.

14. A method for manufacturing a semiconductor device having a CMOS logic circuit and an analog capacitor, comprising:
forming an insulation layer, a lower metal layer, a dielectric layer and an upper metal layer on a semiconductor substrate;
forming, on the upper metal layer, an protective insulation layer wherein an etching selectivity of the lower metal layer to the protective insulation layer is high;
patterning the upper metal layer to form an upper electrode of the analog capacitor;
patterning the lower metal layer to form a lower electrode of the analog capacitor and a wiring for the CMOS logic circuit;
depositing and planarizing an insulation layer;
forming a via contact; and
forming a metal wiring layer.

15. The method of claim 14, wherein the protective insulation layer is made of SiN, SiON or SiO₂.

16. The method of claim 14, wherein the protective insulation layer is a composite layer of SiN/SiO₂.

17. The method of claim 14, wherein the protective insulation layer has a thickness of 0.05 μm˜0.1 μm.

18. The method of claim 14, wherein a photosensitive film used in patterning the lower metal layer has a thickness of 0.55 μm˜0.75 μm.

19. The method of claim 14, wherein an etching selectivity of the lower metal layer with respect to the protective insulation layer is between 5 and 10.
